(19) United States
(12) Patent Application Publication
(10) Pub. No.: US 2012/0064441 A1
(43) Pub. Date: Mar. 15, 2012

(54) METHOD FOR PHOTO-ALIGNMENT TREATMENT, MASK FOR PHOTO-ALIGNMENT TREATMENT, AND METHOD FOR PRODUCING ALIGNMENT FILM

(76) Inventor: Shigeki Tanaka, Osaka (JP)

(21) Appl. No.: 13/320,608

(22) PCT Filed: Mar. 31, 2010
(86) PCT No.: PCT/JP2010/055866

§ 371 Date: Nov. 15, 2011

(30) Foreign Application Priority Data
May 29, 2009 (JP) 2009-131523

(51) Int. Cl. G03F 7/20; G03F 1/48

(52) U.S. Cl. 430/5; 430/321

(57) ABSTRACT

A method for photo-alignment treatment in which at least the number of kinds of photo masks or the number of exposure that are necessary for domain division can be reduced. The method for forming domains 8A, 8B, which are sectioned with respect to alignment regulation directions 11A, 11B, on a surface of an alignment film material 1 that develops alignment regulation powers to align liquid crystal molecules in accordance with irradiation directions of light includes irradiating the alignment film material surface from different directions with different kinds of linear polarized light 9A, 9B that have different planes of vibration through different kinds of polarizing plates 4A, 4B, the polarizing plates having transmission axes 6A, 6B being flush with the planes of vibration, and being disposed corresponding to the domains, wherein a mask 3 comprises the polarizing plates, and a light shielding supporting frame 5 arranged to support the polarizing plates.

### TECHNICAL FIELD

The present invention relates to a method for photo-alignment treatment for forming divided faces for liquid crystal alignment on a surface of an alignment film material by photo-irradiation, a mask for photo-alignment treatment used in the photo-alignment treatment method, and a method for producing an alignment film.

### BACKGROUND ART

Conventionally, a multi-domain liquid crystal display device is known for its excellent viewing angle characteristic. In the liquid crystal display device of this type, each pixel is divided into multiple domains arranged to make directions of inclination of liquid crystal molecules different from each other.

The division into multiple domains is applied to liquid crystal display devices of a variety of liquid crystal modes, which include alignment films each including divided faces for liquid crystal alignment that are arranged to regulate the alignment (directions of inclination) of liquid crystal molecules.

These alignment films are made from a photosensitive alignment film material that develops, when irradiated with light such as ultraviolet light in a given direction, an alignment regulation power in accordance with the irradiation direction, and produced by subjecting the photosensitive alignment film material to a photo-alignment treatment. The photo-alignment treatment is generally performed such that photo masks are placed above the alignment film material, and the alignment film material is irradiated with (exposed to) light such as ultraviolet light through the photo masks. The photo masks are made of light shielding plates provided with opening portions that transmit light. The portions other than the opening portions of the photo masks shield light, and only the opening portions transmit light. Thus, the alignment film material is exposed only to the light transmitted by the opening portions, so that alignment regulation powers are developed at exposed portions of the material. Faces (domains) for liquid crystal alignment that have the alignment regulation powers in accordance with the irradiated light and have the shapes of the opening portions are formed through the photo-alignment treatment.

Usually, only one kind of domain is formed on the alignment film material by one shot of photo-irradiation through the photo-alignment treatment using one photo mask described above. In order to form divided faces for liquid crystal alignment consisting of several kinds of domains, it is necessary to prepare photo masks of several kinds at least as many as the domains to be formed, and to perform several shots of photo-irradiation (exposure) as many as the domains to be formed using those photo masks.

PTL1 discloses a technique for producing an alignment film by forming divided faces for liquid crystal alignment on a surface of an alignment film material through a photo-alignment treatment using a photo mask. Taught in PTL 1 is the photo-alignment treatment through which the alignment film material is irradiated with light in directions oblique to the alignment film material surface, and then develops alignment regulation powers in accordance with the irradiation directions of the light. The photo mask taught in PTL1 include a slit-shaped opening portion, and the alignment film material is exposed to the light through the photo mask.

### CITATION LIST

### Patent Literature

PTL 1: WO 2007/086474 A

### SUMMARY OF INVENTION

### Technical Problem

Usually in the conventional method for photo-alignment treatment for forming the divided faces for liquid crystal alignment on the alignment film material surface using the photo mask as described above, only one kind of domain of the face for liquid crystal alignment is formed by one shot of photo-irradiation. Thus, there arises a problem that two or more kinds of domains cannot be formed at the same time by one shot of photo-irradiation (exposure).

In addition, in the conventional method, it is necessary to prepare photo masks of several kinds at least as many as the domains to be formed. Thus, there arises a problem that two or more kinds of domains cannot be formed by one kind of mask.

In order to overcome the problems described above, preferred embodiments of the present invention provide a method for photo-alignment treatment in which at least the number of kinds of necessary photo masks or the number of exposure can be reduced.

### Solution to Problem

A preferred embodiment of the present invention provides a method for photo-alignment treatment for forming domains, which are sectioned with respect to alignment regulation directions, on a surface of an alignment film material that develops alignment regulation powers to align liquid crystal molecules in accordance with irradiation directions of light, the method including irradiating the alignment film material surface from different directions with different kinds of linear polarized light that have different planes of vibration through different kinds of polarizing plates, the polarizing plates having transmission axes being flush with the planes of vibration of the corresponding different kinds of linear polarized light, and being disposed corresponding to the domains, wherein a mask includes the polarizing plates, and a light shielding supporting frame arranged to support the polarizing plates.

It is preferable that the irradiation of the alignment film material surface from the different directions with the different kinds of linear polarized light that have the different planes of vibration is performed at the same time. This is because different kinds of domains can be formed at the same time, which can reduce the number of processes of photo-irradiation.

It is preferable that the planes of vibration are perpendicular to each other in the method.

It is preferable that the transmission axes are perpendicular to each other in the method.

In another aspect of the present invention, a mask for photo-alignment treatment that is used for irradiating a surface of an alignment film material, which develops alignment regulation powers to align liquid crystal molecules in accordance with irradiation directions of light, with different kinds of linear polarized light that have different planes of vibration through different kinds of polarizing plates provided to the mask, and forming domains, which are sectioned with respect to alignment regulation directions, on the alignment film material surface includes the polarizing plates that have transmission axes being flush with the planes of vibration of the corresponding different kinds of linear polarized light, and are disposed corresponding to the domains, and a light shielding supporting frame arranged to support the polarizing plates.

It is preferable that the transmission axes are perpendicular to each other in the mask.

In another aspect of the present invention, a method for producing an alignment film includes a process of forming domains, which are sectioned with respect to alignment regulation directions, on a surface of an alignment film material that develops alignment regulation powers to align liquid crystal molecules in accordance with irradiation directions of light, the process including irradiating the alignment film material surface from different directions with different kinds of linear polarized light that have different planes of vibration through different kinds of polarizing plates, the polarizing plates having transmission axes being flush with the planes of vibration of the corresponding different kinds of linear polarized light, and being disposed corresponding to the domains, wherein a mask includes the polarizing plates, and a light shielding supporting frame arranged to support the polarizing plates.

It is preferable that the irradiation of the alignment film material surface from the different directions with the different kinds of linear polarized light that have the different planes of vibration is performed at the same time.

It is preferable that the planes of vibration are perpendicular to each other in the method.

It is preferable that the transmission axes are perpendicular to each other in the method.

### Advantageous Effects of Invention

The method for photo-alignment treatment according to the preferred embodiments of the present invention allows at least the number of kinds of necessary masks to be reduced.

In addition, using the mask for photo-alignment treatment according to the preferred embodiments of the present invention in the photo-alignment treatment allows domains, which are sectioned with respect to alignment regulation powers, to be formed on a surface of an alignment film material by one kind of mask.

In addition, the method for producing the alignment film according to the preferred embodiments of the present invention allows at least the number of kinds of necessary masks to be reduced.

### BRIEF DESCRIPTION OF DRAWINGS

FIG. 1 is a schematic view (perspective view) illustrating a relation among an irradiation direction of light that is projected onto a surface of an alignment film material, a direction of an alignment regulation power (alignment regulation direction) that is developed in accordance with the irradiation direction of the light, and a direction of inclination of a liquid crystal molecule.

FIG. 2 is a schematic view (perspective view) illustrating a method for photo-alignment treatment according to a first preferred embodiment of the present invention.

FIG. 3 is a schematic view (cross-sectional view) illustrating a configuration of a liquid crystal display device that includes alignment films produced in a method for photo-alignment treatment according to a second preferred embodiment of the present invention.

FIG. 4 is a schematic view (plan view) illustrating a part of an alignment film formed on a TFT substrate.

FIG. 5 is a schematic view (plan view) illustrating a mask that is used for forming domains arranged to align liquid crystal molecules on a surface of material of the alignment film shown in FIG. 4.

FIG. 6 is a schematic view (perspective view) illustrating a process of photo-alignment treatment in an area of the mask, which is enclosed with the dashed-dotted line in FIG. 5.

FIG. 7 is a schematic view (plan view) illustrating a part of an alignment film formed on a CF substrate.

FIG. 8 is a schematic view (plan view) illustrating a mask that is used for forming domains arranged to align liquid crystal molecules on a surface of material of the alignment film shown in FIG. 7.

FIG. 9 is a schematic view illustrating directions of inclination of liquid crystal molecules in one pixel at a time when a voltage is applied between the TFT substrate and the CF substrate in the liquid crystal display device shown in FIG. 3.

FIG. 10 is a schematic view (plan view) illustrating a mask that is used in a method for photo-alignment treatment according to a third preferred embodiment of the present invention.

FIG. 11 is a schematic view (plan view) illustrating an alignment film material that is subjected to a photo-alignment treatment using the mask shown in FIG. 10.

FIG. 12 is a schematic view (plan view) illustrating a mask that is used in a method for photo-alignment treatment according to a fourth preferred embodiment of the present invention.

FIG. 13 is a schematic view (plan view) illustrating an alignment film material that is subjected to a photo-alignment treatment using the mask shown in FIG. 12.

FIG. 14 is a schematic view (plan view) illustrating a mask that is used in a method for photo-alignment treatment according to a fifth preferred embodiment of the present invention.

FIG. 15 is a schematic view (plan view) illustrating an alignment film material that is subjected to a photo-alignment treatment using the mask shown in FIG. 14.

FIG. 16 is a schematic view (plan view) illustrating one of masks that are used in a method for photo-alignment treatment according to a sixth preferred embodiment of the present invention.

FIG. 17 is a schematic view (plan view) illustrating the other mask that is used in the method for photo-alignment treatment according to the sixth preferred embodiment of the present invention.

FIG. 18 is a schematic view (plan view) illustrating an alignment film material that is subjected to a photo-alignment treatment using the masks shown in FIGS. 16 and 17.

FIG. 19 is a schematic view (cross-sectional view) illustrating a method for photo-alignment treatment according to another preferred embodiment of the present invention.

### DESCRIPTION OF EMBODIMENTS

A detailed description of a method for photo-alignment treatment according to preferred embodiments of the present invention will now be provided with reference to the accompanying drawings. The present invention is not limited to the preferred embodiments described in the present specification.

### First Preferred Embodiment of the Present Invention

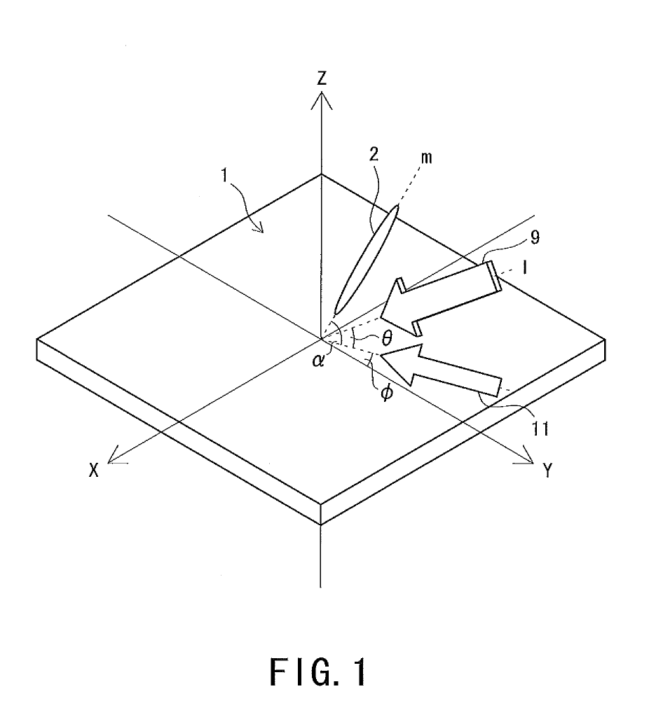

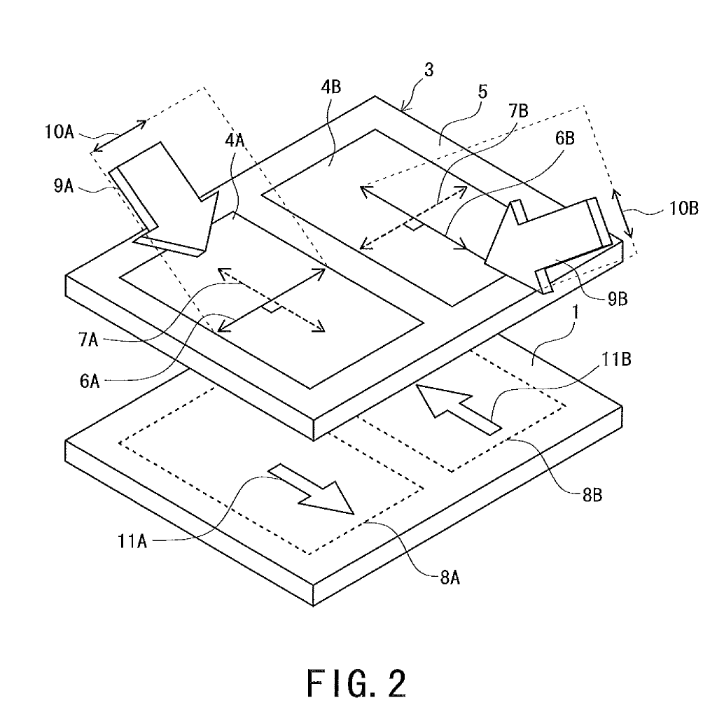

A detailed description of a method for photo-alignment treatment according to a first preferred embodiment of the present invention is provided with reference to FIGS. 1 and 2.

<Method for Photo-Alignment Treatment>

The method for photo-alignment treatment for forming domains, which are sectioned with respect to alignment regulation directions, on a surface of an alignment film material that develops alignment regulation powers to align liquid crystal molecules in accordance with irradiation directions of light includes irradiating the alignment film material surface from different directions with different kinds of linear polarized light that have different planes of vibration through different kinds of polarizing plates, the polarizing plates having transmission axes being flush with the planes of vibration of the corresponding different kinds of linear polarized light, and being disposed corresponding to the domains, wherein a mask includes the polarizing plates, and a light shielding supporting frame arranged to support the polarizing plates.

First, the alignment film material used in the method for photo-alignment treatment is described. The alignment film material is preferably a photosensitive material. Irradiated with light such as ultraviolet light in a given direction, the photosensitive material causes photo reaction such as photo somerization reaction and photodimerization reaction in accordance with the irradiation direction of the light, and develops an alignment regulation power to align liquid crystal molecules in accordance with the photoreaction. Examples of the alignment film material include a polyimide in which the side chains are substituted with an azobenzene, and a polyimide in which the side chains are substituted with a cinnamate or a coumalin, which are known materials.

Next, an alignment regulation power that the alignment film material develops by photo irradiation is described with reference to FIG. 1. FIG. 1 is a schematic view (perspective view) illustrating a relation among an irradiation direction 1 of light 9 that is projected onto a surface of an alignment film material 1, a direction of an alignment regulation power 11 (alignment regulation direction) that is developed in accordance with the irradiation direction 1, and a direction m of inclination of a liquid crystal molecule 2. When the surface (X-Y plane) of the alignment film material 1 is irradiated with the light 9 such as ultraviolet light in the irradiation direction 1 at an angle θ, the photosensitive material 1 causes photoreaction at an area irradiated with the light 9 and develops an alignment regulation power 11 in accordance with the irradiation direction 1, as shown in FIG. 1. For the sake of illustration, the alignment regulation power (alignment regulation direction) 11 is indicated in FIG. 1 as a component that is along the surface of the alignment film material 1 (same applies to the other drawings).

The alignment regulation power 11 that is developed in accordance with the irradiation direction 1 acts to align the orientation of the liquid crystal molecule 2. As shown in FIG. 1, being above the alignment film material 1 having the alignment regulation power 11, the liquid crystal molecule 2 is aligned so as to be inclined (inclinedly aligned) at an angle α with respect to the surface of the alignment film material 1 by the action of the alignment regulation power 11. That is, the inclination direction m (the inclined angle α) of the liquid crystal molecule 2 is determined by the irradiation direction 1 (the irradiation angle θ). Linear polarized light is preferably used as the light 9 in the present preferred embodiments of the present invention. The irradiation angle θ is set appropriately within the range of 0 degree <θ<90 degrees.

Next, the method for photo-alignment treatment according to the present preferred embodiment of the present invention is described with reference to FIG. 2. FIG. 2 is a schematic view (perspective view) illustrating the method for photo-alignment treatment according to the first preferred embodiment of the present invention. The alignment film material 1, and a mask (mask for photo-alignment treatment) 3 disposed above the alignment film material 1 are shown in FIG. 2. The mask 3 includes two kinds of polarizing plates 4A and 4B, of which transmission axes are different in direction, and a light shielding frame member 5 that surrounds the polarizing plates 4A and 4B and is arranged to shield light.

The polarizing plates 4A and 4B according to the present preferred embodiment of the present invention have a rectangular shape, and are disposed side by side. The polarizing plate 4A has, in its plane, a transmission axis 6A and an absorption axis 7A that intersect at right angles. The polarizing plate 4B has, in its plane, a transmission axis 6B and an absorption axis 7B that intersect at right angles. In the present preferred embodiment of the present invention, the polarizing plates 4A and 4B are disposed such that the transmission axes 6A and 6B are vertical (perpendicular) to each other. In addition, the polarizing plates 4A and 4B are disposed above the alignment film material 1 so as to correspond to domains 8A and 8B that are to be formed on the surface of the alignment film material 1.

In the method for photo-alignment treatment according to the present preferred embodiment of the present invention, the linear polarized light 9A is projected onto the polarizing plate 4A, and the linear polarized light 9B is projected onto the polarizing plate 4B of the mask 3 disposed above the alignment film material 1 as shown in FIG. 2.

The linear polarized light 9A is projected obliquely onto the surface of the alignment film material 1 from a light source (not shown). A travelling direction (irradiation direction) of the linear polarized light 9A is set based on the domain 8A that is to be formed on the surface of the alignment film material 1. To be specific, the travelling direction is set based on an alignment regulation power (alignment regulation direction) 11A that is desired to be developed in the domain 8A. A vibration direction (a polarizing axis 10A) of the linear polarized light 9A is set based on the transmission axis 6A of the polarizing plate 4A. The polarizing axis 10A of the linear polarized light 9A is disposed flush with the transmission axis 6A of the polarizing plate 4A. To be specific, the linear polarized light 9A is set such that its plane of vibration (plane including the polarizing axis 10A) is disposed flush with the transmission axis 6A of the polarizing plate 4A. In the present preferred embodiment of the present invention, the polarizing axis 10A of the linear polarized light 9A is disposed especially parallel to the transmission axis 6A of the polarizing plate 4A. The linear polarized light 9A can pass through the polarizing plate 4A, and thus the alignment film material 1 can be exposed to the linear polarized light 9A. The linear polarized light 9A that is projected onto the light shielding frame member 5 is shielded thereby. Thus, the domain 8A that has the alignment regulation power 11A in accordance with the travelling direction (irradiation direction) of the linear polarized light 9A and has the shape of the polarizing plate 4A is formed on the alignment film material 1.

Meanwhile, the linear polarized light 9B is projected obliquely onto the surface of the alignment film material 1 from a light source (not shown). A travelling direction (irradiation direction) of the linear polarized light 9B is set based on the domain 8B that is to be formed on the surface of the alignment film material 1. To be specific, the travelling direction is set based on an alignment regulation power (alignment regulation direction) 11B that is desired to be developed in the domain 8B. A vibration direction (a polarizing axis 10B) of the linear polarized light 9B is set based on the transmission axis 6B of the polarizing plate 4B. The polarizing axis 10B of the linear polarized light 9B is disposed flush with the transmission axis 6B of the polarizing plate 4B. To be specific, the linear polarized light 9B is set such that its plane of vibration (plane including the polarizing axis 10B) is disposed flush with the transmission axis 6B of the polarizing plate 4B. The linear polarized light 9B can pass through the polarizing plate 4B, and thus the alignment film material 1 can be exposed to the linear polarized light 9B. The linear polarized light 9B that is projected onto the light shielding frame member 5 is shielded thereby. Thus, the domain 8B that has the alignment regulation power 11B in accordance with the travelling direction (irradiation direction) of the linear polarized light 9B and has the shape of the polarizing plate 4B is formed on the alignment film material 1.

In the present preferred embodiment of the present invention, even when the linear polarized light 9A deviates and is projected onto the polarizing plate 4B, the linear polarized light 9A does not pass through the polarizing plate 4B and is shielded thereby. This is because the plane of vibration (plane including the polarizing axis 10A) of the linear polarized light 9A is disposed flush with the absorption axis 7B of the polarizing plate 4B. Meanwhile, even when the linear polarized light 9B deviates and is projected onto the polarizing plate 4A, the linear polarized light 9B does not pass through the polarizing plate 4A and is shielded thereby. This is because the plane of vibration (plane including the polarizing axis 10B) of the linear polarized light 9B is disposed flush with the absorption axis 7A of the polarizing plate 4A. In the present preferred embodiment of the present invention, the plane of vibration of the linear polarized light 9A and the plane of vibration of the linear polarized light 9B have a positional relation such that they are vertical (perpendicular) to each other.

As described above, in the present preferred embodiment of the present invention, the linear polarized light 9A and the linear polarized light 9B are projected at the same time onto the mask 3, and accordingly the domains 8A and 8B having the alignment regulation directions different from each other can be formed at a time (at the same time) on the alignment film material 1. Thus, the method for photo-alignment treatment according to the present preferred embodiment of the present invention allows the number of processes of photo-irradiation (exposure) to be reduced compared with the conventional method for photo-alignment treatment, which can reduce the time of the photo-alignment treatment.

It is to be noted that in the method for photo-alignment treatment according to the present preferred embodiment of the present invention, the linear polarized light 9A and the linear polarized light 9B may be projected separately. When the linear polarized light 9A and the linear polarized light 9B are projected separately, two different kinds of domains can be formed using one kind of mask. That is, it is unnecessary to prepare masks of several kinds as many as the domains, and unnecessary to change the masks for every irradiation, which are necessary in the conventional method. Consequently, in the method for photo-alignment treatment according to the present preferred embodiment of the present invention, it is unnecessary to per form positional alignment of a mask with respect to an alignment film material every time a different domain is formed, which can improve exposure accuracy. In some of the conventional methods for photo-alignment treatment, different kinds (e.g., two different kinds) of domains can be formed using one kind of mask by shifting (sliding) the position of the mask on the alignment film material for every irradiation (exposure) process; however, it is not a easy task to perform alignment of the mask with precision every time the mask is shifted. In contrast, in the method for photo-alignment treatment according to the present preferred embodiment of the present invention, two kinds of domains can be formed using one kind of mask without shifting the mask.

In the present preferred embodiment of the present invention, the linear polarized light 9A and the linear polarized light 9B are projected from the different light sources because it is preferable to provide a light source for each linear polarized light having a polarizing axis (a plane of vibration).

<Mask for Photo-Alignment Treatment>

A mask for photo-alignment treatment according to the present preferred embodiment of the present invention defines the mask 3 used in the method for photo-alignment treatment described above, which is shown in FIG. 2.

<Method for Producing an Alignment Film>

A method for producing an alignment film according to the present preferred embodiment of the present invention includes the method (process) for photo-alignment treatment described above.

### Second Preferred Embodiment of the Present Invention

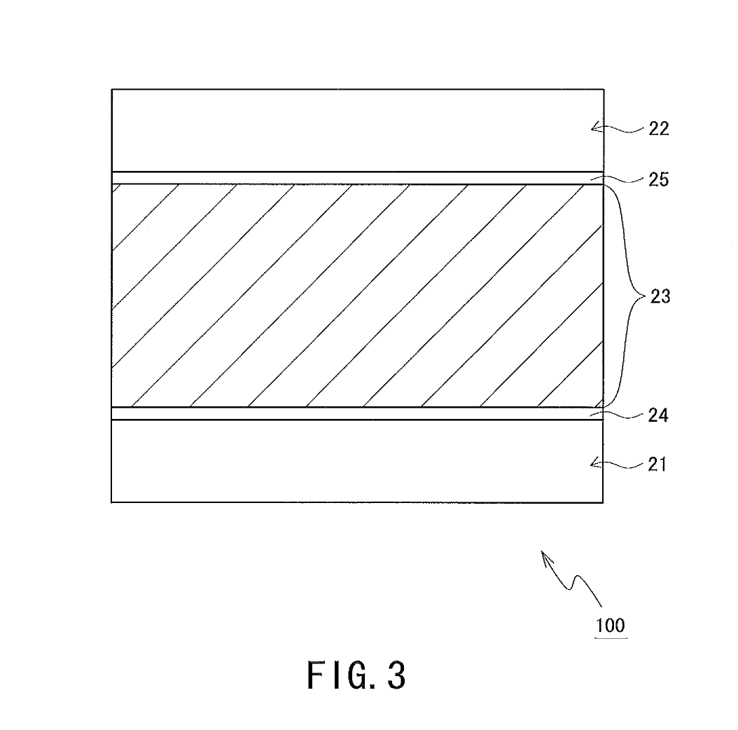

A detailed description of a method for photo-alignment treatment according to a second preferred embodiment of the present invention is provided with reference to FIGS. 3 to 9. FIG. 3 is a schematic view (cross-sectional view) illustrating a configuration of a liquid crystal display device that includes alignment films produced in the method for photo-alignment treatment according to the present preferred embodiment of the present invention. A liquid crystal display device 100 includes a thin film transistor (TFT) substrate 21, a color filter (CF) substrate 22, and a liquid crystal layer 23 as shown in FIG. 3. In FIG. 3, the other constituent elements such as a light source are not shown for the sake of simplicity.

The TFT substrate 21 includes a transparent glass plate on which TFTs that define switching elements and other components are provided. The CF substrate 22 includes a transparent glass plate on which a CF layer and other components are provided. The TFT substrate 21 and the CF substrate 22 are opposed to each other sandwiching the liquid crystal layer 23. The liquid crystal layer 23 contains nematic liquid crystals having negative dielectric anisotropy (contains negative nematic liquid crystals). The TFT substrate 21 includes an alignment film 24 on its surface on the side where the liquid crystal layer 23 is. The CF substrate 22 includes an alignment film 25 on its surface on the side where the liquid crystal layer 23 is.

The liquid crystal display device 100 is a four-domain VATN (Vertical Alignment Twisted Nematic) mode LCD. In the VATN mode, the alignment films (vertical alignment films) are used, which have alignment treatment directions (alignment regulation directions) that intersect at right angles when disposed on the substrates (TFT substrate 21 and CF substrate 22), whereby the liquid crystal molecules are aligned in a vertical direction and twisted.

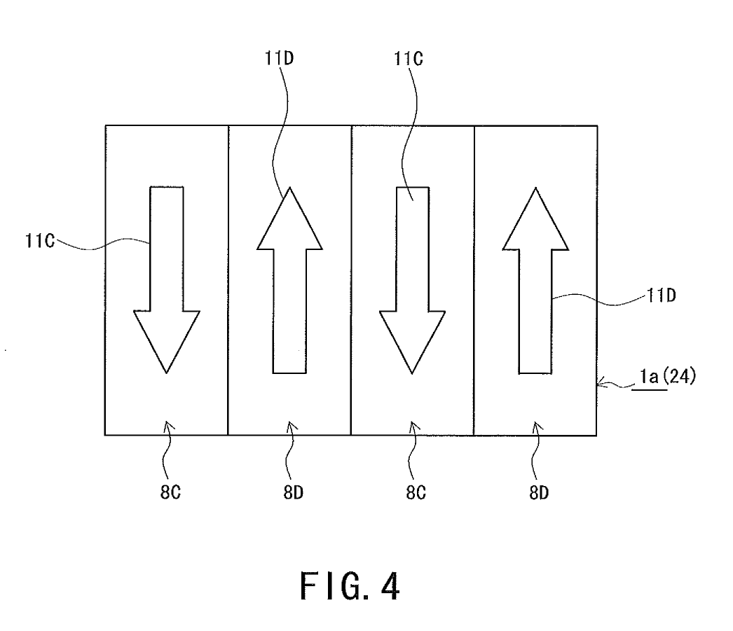

FIG. 4 is a schematic view (plan view) illustrating apart of the alignment film 24 formed on the TFT substrate 21. The alignment film 24 includes two kinds of domains 8C and domains 8D for aligning liquid crystal molecules that are formed on a surface of an alignment film material 1a as shown in FIG. 4. The domains 8C and the domains 8D have alignment regulation powers (alignment regulation directions) 11C and alignment regulation powers (alignment regulation directions) 11D respectively, where the alignment regulation powers 11C are different from the alignment regulation powers 11D. Shown in FIG. 4 are the two domains 8C and the two domains 8D that are disposed alternately, where the alignment regulation powers 11C and the alignment regulation powers 11D are indicated with the arrows in directions opposite to each other.

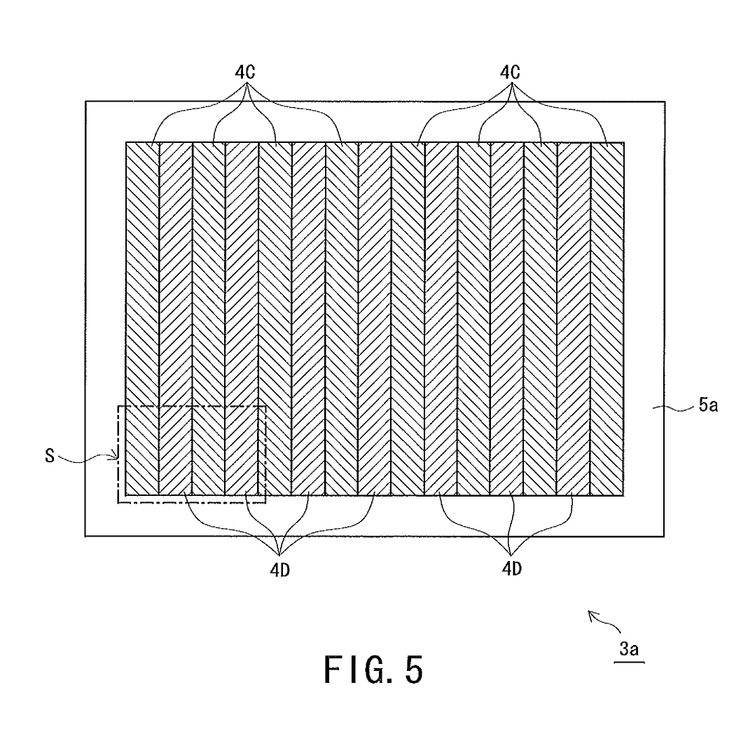

FIG. 5 is a schematic view (plan view) illustrating a mask 3a that is used for forming the domains 8C and 8D for aligning liquid crystal molecules on the surface of the alignment film material 1a. The mask 3a includes two kinds of polarizing plates 4C and polarizing plates 4D, of which transmission axes (absorption axes) are different indirection, and a light shielding frame member 5a as shown in FIG. 5. The polarizing plates 4C are arranged to form the domains 8C shown in FIG. 4. The polarizing plates 4D are arranged to form the domains 8D shown in FIG. 4. The polarizing plates 4C and 4D have a reed (rectangular) shape, and are disposed alternately. The polarizing plates 4C and 4D are surrounded and supported by the light shielding frame member 5a.

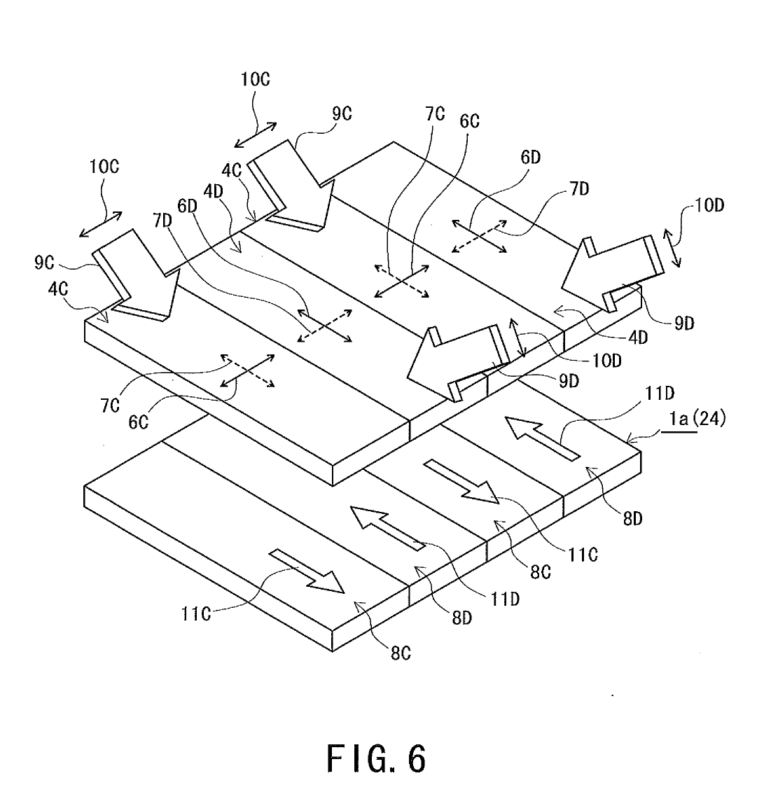

FIG. 6 is a schematic view (perspective view) illustrating the method for photo-alignment treatment in an area S of the mask 3a, which is enclosed with the dashed-dotted line in FIG. 5. In the method for photo-alignment treatment according to the present preferred embodiment of the present invention, linear polarized light 9O is projected obliquely onto the surface of the alignment film material 1a through the polarizing plate 4C, while linear polarized light 9D is projected obliquely onto the surface of the alignment film material 1a through the polarizing plate 40 of the mask 3a disposed above the alignment film material 1a, as shown in FIG. 6. In the present preferred embodiment of the present invention, the linear polarized light 9C and the linear polarized light 9D are projected at the same time from different light sources (not shown). As shown in FIG. 6, planes of vibration of the linear polarized light 9C (planes including polarizing axes 100) are disposed flush with transmission axes 6C of the polarizing plates 4C, and planes of vibration of the linear polarized light 9D (planes including polarizing axes 10D) are disposed flush with transmission axes 6D of the polarizing plates 4D. Absorption axes 7C and 7D, and the transmission axes 6C and 6D intersect at right angles, respectively.

Through the photo-alignment treatment under these conditions, the domains 8C and 8D that have the alignment regulation powers 11C and 11D in accordance with the irradiation directions of the linear polarized light 9C and 9D, and have the shapes of the polarizing plates 4C and 4D respectively are formed on the alignment film material 1a as shown in FIG. 6. The alignment film material 1a shown in FIG. 6 is used for the alignment film 24 of the liquid crystal display device 100 shown in FIG. 3.

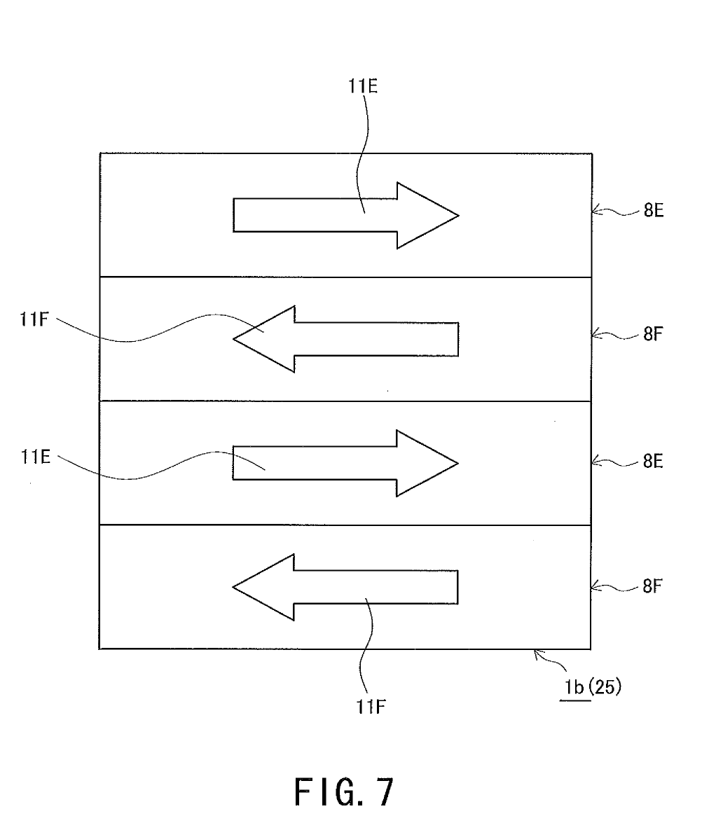

FIG. 7 is a schematic view (plan view) illustrating a part of the alignment film 25 formed on the CF substrate 22. The alignment film 25 includes two kinds of domains 8E and domains 8F for aligning liquid crystal molecules that are formed on a surface of an alignment film material 1b as shown in FIG. 7. The domains 8E and the domains 8F have alignment regulation powers (alignment regulation directions) 11E and alignment regulation powers (alignment regulation directions) 11F respectively, where the alignment regulation powers 11E are different from the alignment regulation powers 11F. Shown in FIG. 7 are the two domains 8E and the two domains 8F that are disposed alternately, where the alignment regulation powers 11E and the alignment regulation powers 11F are indicated with the arrows in directions opposite to each other.

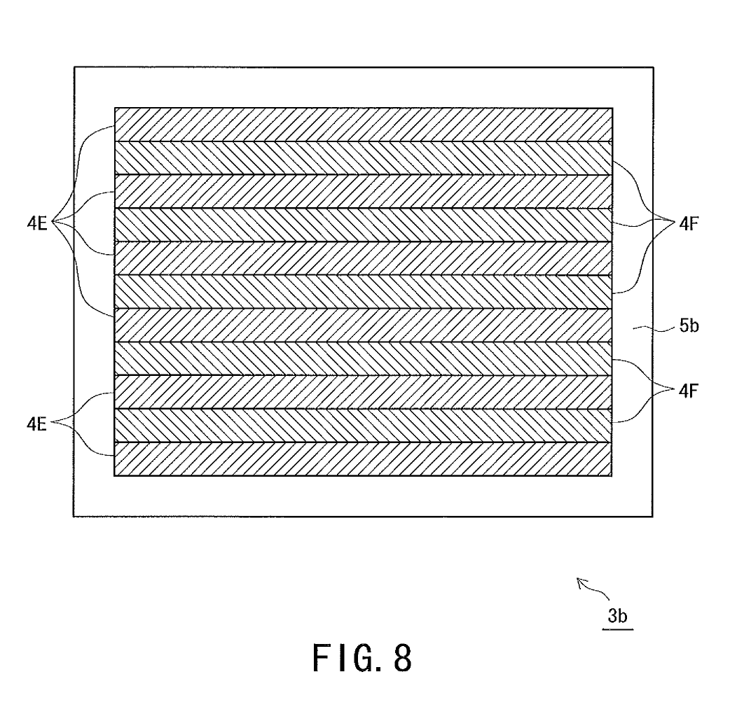

FIG. 8 is a schematic view (plan view) illustrating a mask 3b that is used for forming the domains 8E and 8F for aligning liquid crystal molecules on the surface of the alignment film material 1b shown in FIG. 7. The mask 3b includes two kinds of polarizing plates 4E and polarizing plates 4F, of which transmission axes (absorption axes) are different in direction, and alight shielding frame member 5b as shown in FIG. 8. The polarizing plates 4E are arranged to form the domains 8E shown in FIG. 7. The polarizing plates 4F are arranged to form the domains 8F shown in FIG. 7. The polarizing plates 4E and 4F have a reed (rectangular) shape, and are disposed alternately.

The mask 3b shown in FIG. 8 has a basic configuration same as the mask 3a shown in FIG. 5, which is used for producing the alignment film 24 on the side of the TFT substrate. The principle of the method in which the two kinds of domains 8E and 8F are formed on the surface of the alignment film material 1b shown in FIG. 7 is same as the method shown in FIG. 6. Thus, a description of the method for producing the alignment film 25 on the side of the CF substrate through the alignment treatment using the mask 3b is omitted.

It is to be noted that the alignment film 24 on the TFT substrate's side and the alignment film 25 on the CF substrate's side are different in the directions in which the reed-shaped domains formed on the alignment film material surfaces are aligned. In the liquid crystal display device 100 shown in FIG. 3, the alignment film 24 on the TFT substrate's side and the alignment film 25 on the CF substrate's side that are opposed to each other sandwiching the liquid crystal layer 23 are disposed such that the domains of the alignment film 24 and the domains of the alignment film 25 intersect with each other.

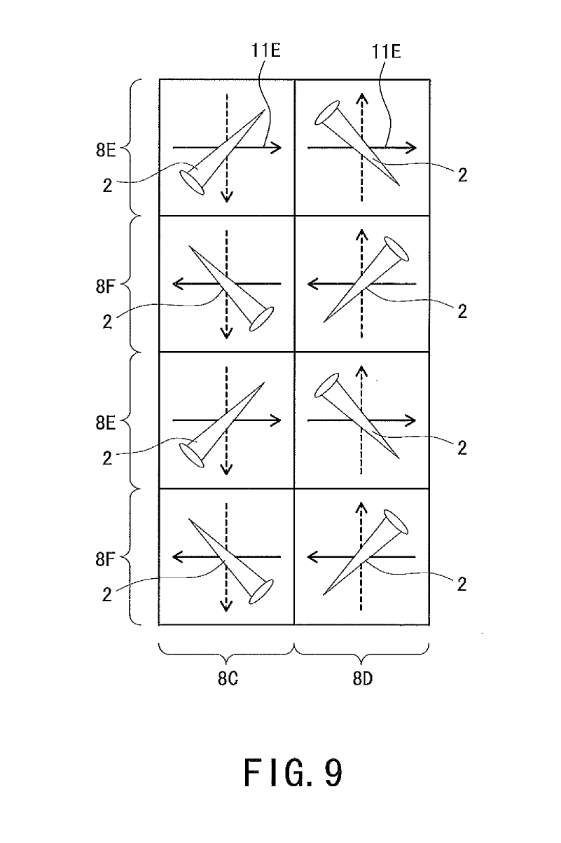

FIG. 9 is a schematic view illustrating directions of inclination of liquid crystal molecules 2 in one pixel at a time when a voltage is applied between the TFT substrate 21 and the CF substrate 22 in the liquid crystal display device 100 shown in FIG. 3. One pixel in the liquid crystal display device 100 is divided into 8 domains as shown in FIG. 9, where four domains are aligned in a longitudinal direction and two domains are aligned in a lateral direction. For the sake of simplicity, shown in FIG. 9 is a case where one liquid crystal molecule 2 is provided in each domain. In FIG. 9, the right arrows in solid lines indicate the alignment regulation powers (alignment regulation directions) 11E that the domains 8E on the alignment film 25 on the CF substrate's side have, and the left arrows in solid lines indicate the alignment regulation powers (alignment regulation directions) 11F that the domains 8F on the alignment film 25 on the CF substrate's side have. In FIG. 9, the down arrows in broken lines indicate the alignment regulation powers (alignment regulation directions) 11C that the domains 8C on the alignment film 24 on the TFT substrate's side have, and the up arrows in broken lines indicate the alignment regulation powers (alignment regulation directions) 11D that the domains 8D on the alignment film 24 on the TFT substrate's side have.

As shown in FIG. 9, the alignment film 24 on the TFT substrate's side and the alignment film 25 on the CF substrate's side are disposed such that their alignment regulation directions are different from each other by 90 degrees in each domain in one pixel. Thus, when the TFT substrate 21 and the CF substrate 22 that are opposed to each other and superpose are seen in a plan view, the liquid crystal molecules in the domains are oriented in directions that deviate by 45 degrees from the respective alignment regulation directions (the irradiation directions) as shown in FIG. 9. The liquid crystal molecules in the domains are inclined in four different directions. Thus, using the alignment film 24 and the alignment film 25 subjected to the alignment treatment according to the present preferred embodiment of the present invention allows the liquid crystal molecules to be aligned twisted by 90 degrees.

### Third Preferred Embodiment of the Present Invention

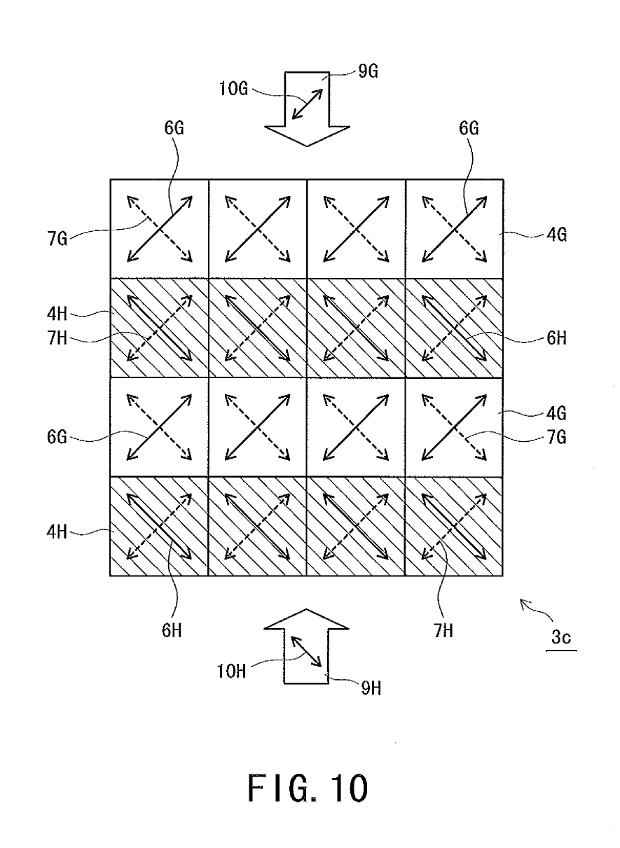

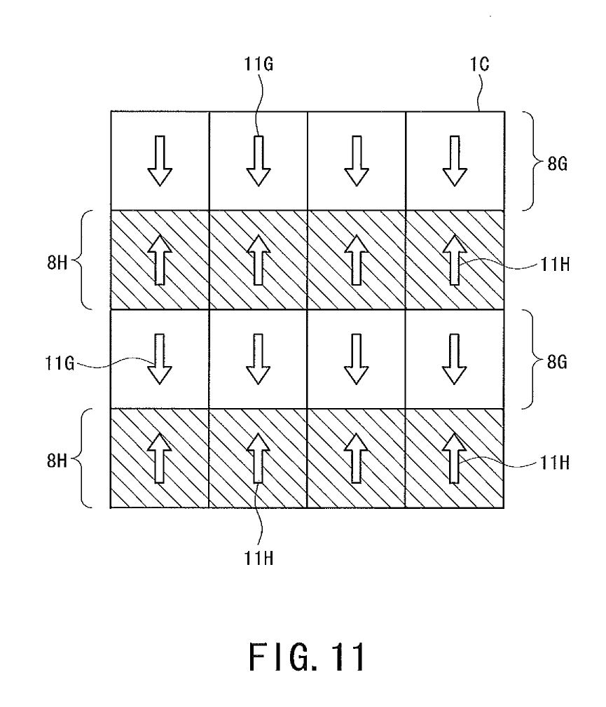

A detailed description of a method for photo-alignment treatment according to a third preferred embodiment of the present invention is provided with reference to FIGS. 10 and 11. FIG. 10 is a schematic view (plan view) illustrating a mask 3c that is used in the method for photo-alignment treatment according to the third preferred embodiment of the present invention. FIG. 11 is a schematic view (plan view) illustrating an alignment film material that is subjected to a photo-alignment treatment using the mask 3c shown in FIG. 10. The mask 3c includes two kinds of polarizing plates 4G and polarizing plates 4H as shown in FIG. 10. Transmission axes 6G of the polarizing plates 4G are indicated with the arrows in solid lines in the polarizing plates 4G in FIG. 10, and absorption axes 7G of the polarizing plates 4G are indicated with the arrows in broken lines in the polarizing plates 4G in FIG. 10. Transmission axes 6H of the polarizing plates 4H are indicated with the arrows in solid lines in the polarizing plates 4H in FIG. 10, and absorption axes 7H of the polarizing plates 4H are indicated with the arrows in broken lines in the polarizing plates 4H in FIG. 10. The transmission axes 6G and the absorption axes 7G of the polarizing plates 4G intersect at right angles, and the transmission axes 6H and the absorption axes 7H of the polarizing plates 4H intersect at right angles. The transmission axes 6G of the polarizing plates 4G and the transmission axes 6H of the polarizing plates 4H are disposed vertical (perpendicular) to each other.

The mask 3c shown in FIG. 10 is placed above an alignment film material, and the alignment film material is irradiated with linear polarized light 9G through the polarizing plates 4G and with linear polarized light 9H through the polarizing plates 4H of the mask 3c, whereby an alignment film material 1c shown in FIG. 11 is obtained. The linear polarized light 9G and the linear polarized light 9H are projected obliquely onto a surface of the alignment film material from different light sources (not shown). The linear polarized light 9G and the linear polarized light 9H are set to face each other when the mask 3c shown in FIG. 10 is seen in a plan view. In the present preferred embodiment of the present invention, a plane of vibration of the linear polarized light 9G (plane including a polarizing axis 10G) is disposed flush with transmission axes 6G of the polarizing plates 4G, and a plane of vibration of the linear polarized light 9H (plane including a polarizing axis 10H) is disposed flush with transmission axes 6H of the polarizing plates 4H. Domains 8G having alignment regulation powers (alignment regulation directions) 11G and domains 8H having alignment regulation powers (alignment regulation directions) 11H are formed on a surface of the alignment film material 1c shown in FIG. 11. The domains 8G are formed by the linear polarized light 9G having passed through the polarizing plates 4G, and the domains 8H are formed by the linear polarized light 9H having passed through the polarizing plates 4H of the mask 3c shown in FIG. 10. In the present preferred embodiment of the present invention, the linear polarized light 9G and the linear polarized light 9H may be projected at the same time, or may be projected separately.

### Fourth Preferred Embodiment of the Present Invention

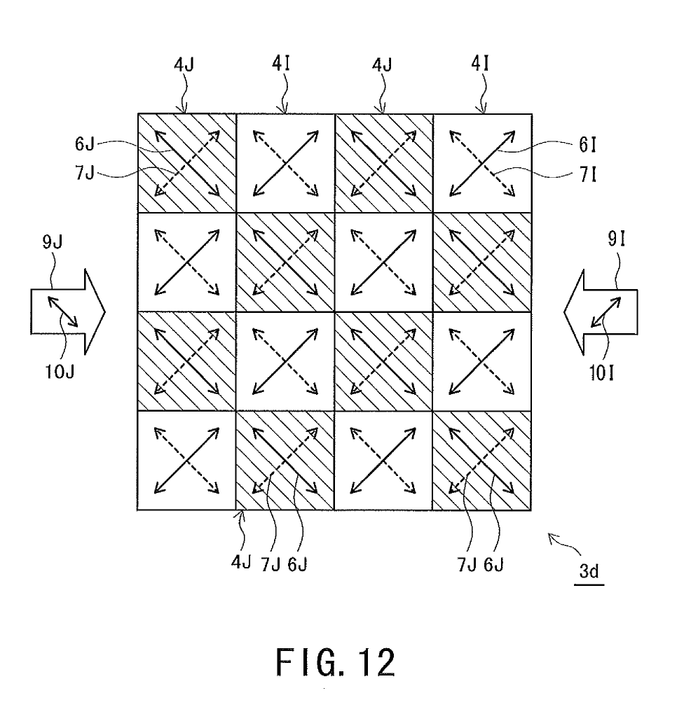

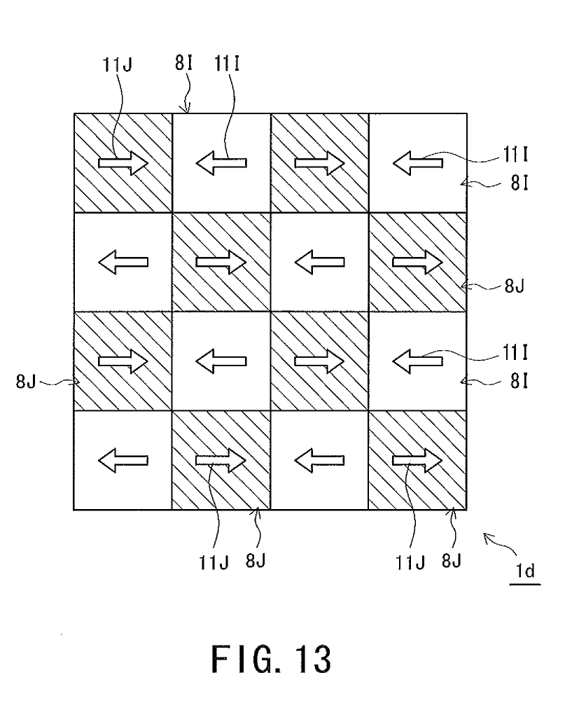

A detailed description of a method for photo-alignment treatment according to a fourth preferred embodiment of the present invention is provided with reference to FIGS. 12 and 13. FIG. 12 is a schematic view (plan view) illustrating a mask 3d that is used in the method for photo-alignment treatment according to the fourth preferred embodiment of the present invention. FIG. 13 is a schematic view (plan view) illustrating an alignment film material that is subjected to a photo-alignment treatment using the mask 3d shown in FIG. 12. The mask 3d includes two kinds of polarizing plates 4I and polarizing plates 4J as shown in FIG. 12. Transmission axes 6I of the polarizing plates 4I are indicated with the arrows in solid lines in the polarizing plates 4I in FIG. 12, and absorption axes 7I of the polarizing plates 4I are indicated with the arrows in broken lines in the polarizing plates 4I in FIG. 12. Transmission axes 6J of the polarizing plates 4J are indicated with the arrows in solid lines in the polarizing plates 4J in FIG. 12, and absorption axes 7J of the polarizing plates 4J are indicated with the arrows in broken lines in the polarizing plates 4J in FIG. 12. The transmission axes 6I and the absorption axes 7I of the polarizing plates 4I intersect at right angles, and the transmission axes 6J and the absorption axes 7J of the polarizing plates 4J intersect at right angles. The transmission axes 6I of the polarizing plates 4I and the transmission axes 6J of the polarizing plates 4J are disposed vertical (perpendicular) to each other. As shown in FIG. 12, the polarizing plates 4I and the polarizing plates 4J are disposed alternately both in a longitudinal direction and in a latitude direction in the mask 3d.

The mask 3d shown in FIG. 12 is placed above an alignment film material, and the alignment film material is irradiated with linear polarized light 9I through the polarizing plates 4I and with linear polarized light 9J through the polarizing plates 4J of the mask 3d, whereby an alignment film material 1d shown in FIG. 13 is obtained. The linear polarized light 9I and the linear polarized light 9J are projected obliquely onto a surface of the alignment film material from different light sources (not shown). The linear polarized light 9I and the linear polarized light 9J are set to face each other when the mask 3d shown in FIG. 12 is seen in a plan view. In the present preferred embodiment of the present invention, a plane of vibration of the linear polarized light 9I (plane including a polarizing axis 10I) is disposed flush with transmission axes 6I of the polarizing plates 4I, and a plane of vibration of the linear polarized light 9J (plane including a polarizing axis 10J) is disposed flush with transmission axes 6J of the polarizing plates 4J. Domains 81 having alignment regulation powers (alignment regulation directions) 11I and domains 8J having alignment regulation powers (alignment regulation directions) 11J are formed on a surface of the alignment film material 1d shown in FIG. 13. The domains 81 are formed by the linear polarized light 9I having passed through the polarizing plates 4I, and the domains 8J are formed by the linear polarized light 9J having passed through the polarizing plates 4J of the mask 3d shown in FIG. 12. In the present preferred embodiment of the present invention, the linear polarized light 9I and the linear polarized light 9J may be projected at the same time, or may be projected separately.

### Fifth Preferred Embodiment of the Present Invention

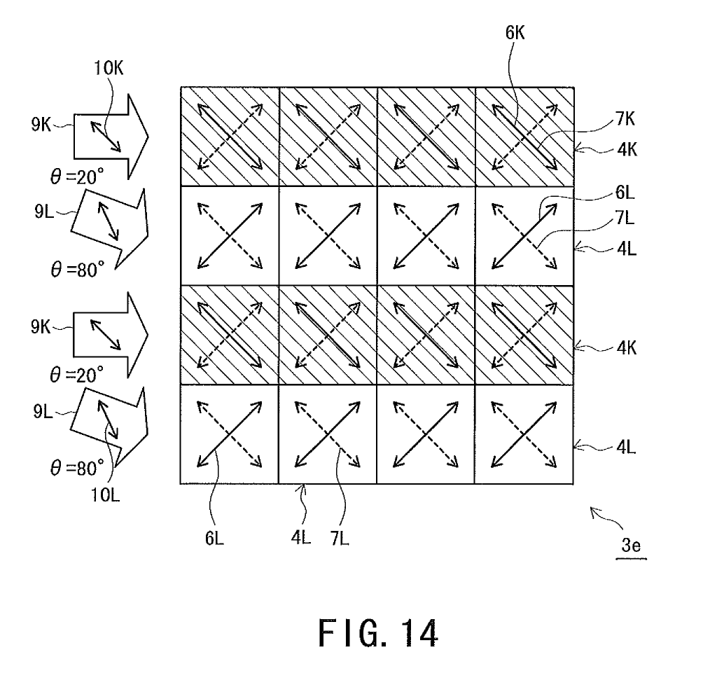

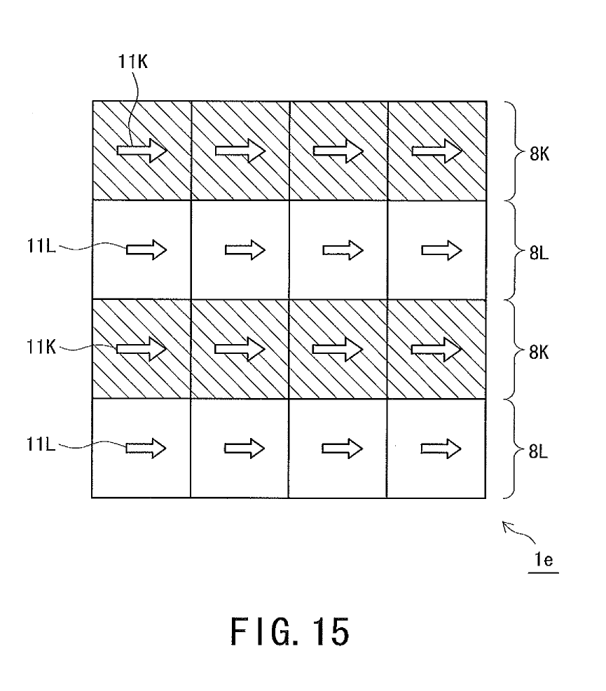

A detailed description of a method for photo-alignment treatment according to a fifth preferred embodiment of the present invention is provided with reference to FIGS. 14 and 15. FIG. 14 is a schematic view (plan view) illustrating a mask 3e that is used in the method for photo-alignment treatment according to the fifth preferred embodiment of the present invention. FIG. 15 is a schematic view (plan view) illustrating an alignment film material that is subjected to a photo-alignment treatment using the mask 3e shown in FIG. 14. The mask 3e includes two kinds of polarizing plates 4K and polarizing plates 4L as shown in FIG. 14. Transmission axes 6K of the polarizing plates 4K are indicated with the arrows in solid lines in the polarizing plates 4K in FIG. 14, and absorption axes 7K of the polarizing plates 4K are indicated with the arrows in broken lines in the polarizing plates 4K in FIG. 14. Transmission axes 6L of the polarizing plates 4L are indicated with the arrows in solid lines in the polarizing plates 4L in FIG. 14, and absorption axes 7L of the polarizing plates 4L are indicated with the arrows in broken lines in the polarizing plates 4L in FIG. 14. The transmission axes 6K and the absorption axes 7K of the polarizing plates 4K intersect at right angles, and the transmission axes 6L and the absorption axes 7L of the polarizing plates 4L intersect at right angles. The transmission axes 6K of the polarizing plates 4K and the transmission axes 6L of the polarizing plates 4L are disposed vertical (perpendicular) to each other.

The mask 3e shown in FIG. 14 is placed above an alignment film material, and the alignment film material is irradiated with linear polarized light 9K through the polarizing plates 4K and with linear polarized light 9L through the polarizing plates 4L of the mask 3e, whereby an alignment film material 1e shown in FIG. 15 is obtained. In the present preferred embodiment of the present invention, the linear polarized light 9K and the linear polarized light 9L are projected obliquely onto a surface of the alignment film material from different light sources (not shown). The linear polarized light 9K and the linear polarized light 9L have different angles of incidence to the alignment film material surface (see θ in FIG. 1). The angle of incidence of the linear polarized light 9K (the irradiation angle θ=20 degrees) is set smaller than the angle of incidence of the linear polarized light 9L (the irradiation angle θ=80 degrees). The linear polarized light 9K and the linear polarized light 9L are set to be oriented in the same direction when the mask 3e shown in FIG. 14 is seen in a plan view. In the present preferred embodiment of the present invention, planes of vibration of the linear polarized light 9K (planes including polarizing axes 10K) are disposed flush with transmission axes 6K of the polarizing plates 4K, and planes of vibration of the linear polarized light 9L (planes including polarizing axes 10L) are disposed flush with transmission axes 6L of the polarizing plates 4L. Domains 8K having alignment regulation powers (alignment regulation directions) 11K and domains 8L having alignment regulation powers (alignment regulation directions) 11L are formed on a surface of the alignment film material 1e shown in FIG. 15. The domains 8K are formed by the linear polarized light 9K having passed through the polarizing plates 4K, and the domains 8L are formed by the linear polarized light 9L having passed through the polarizing plates 4L of the mask 3e shown in FIG. 14. In the present preferred embodiment of the present invention, the linear polarized light 9K and the linear polarized light 9L may be projected at the same time, or may be projected separately.

### Sixth Preferred Embodiment of the Present Invention

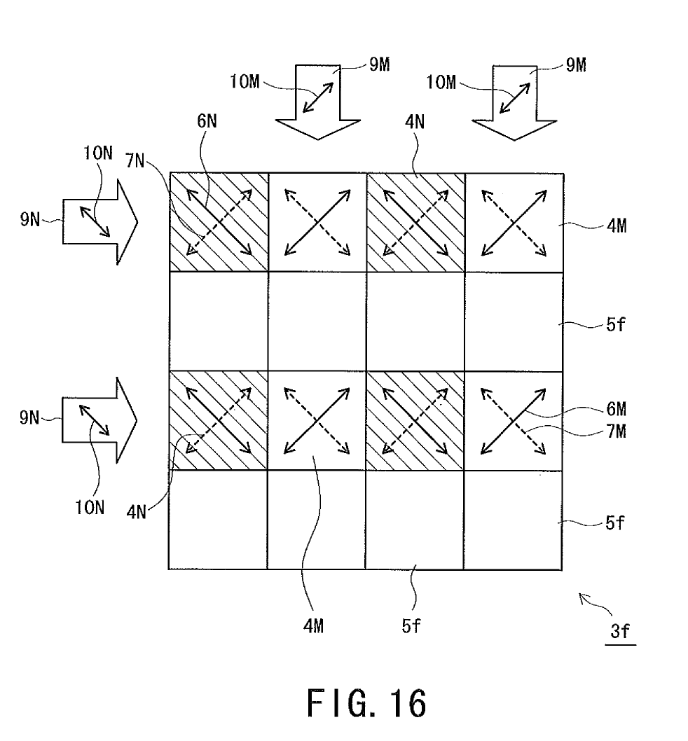

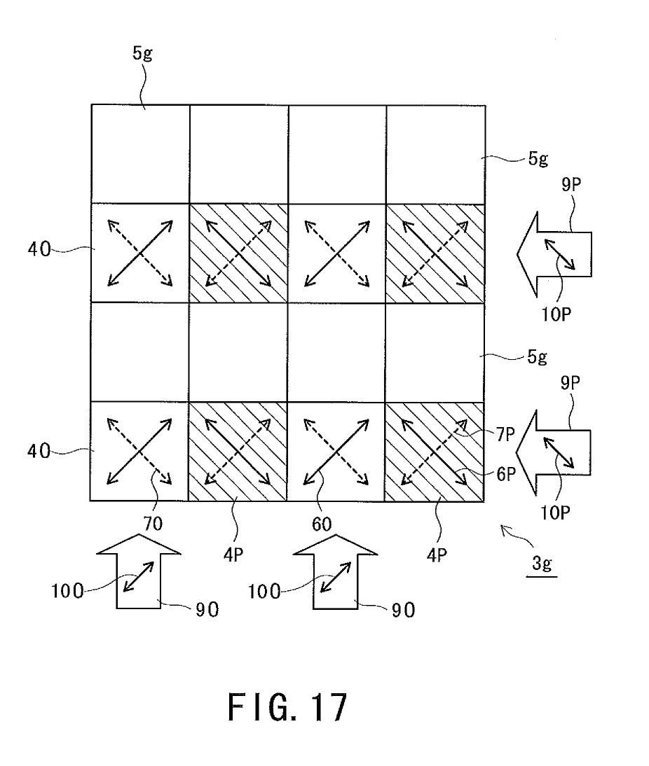

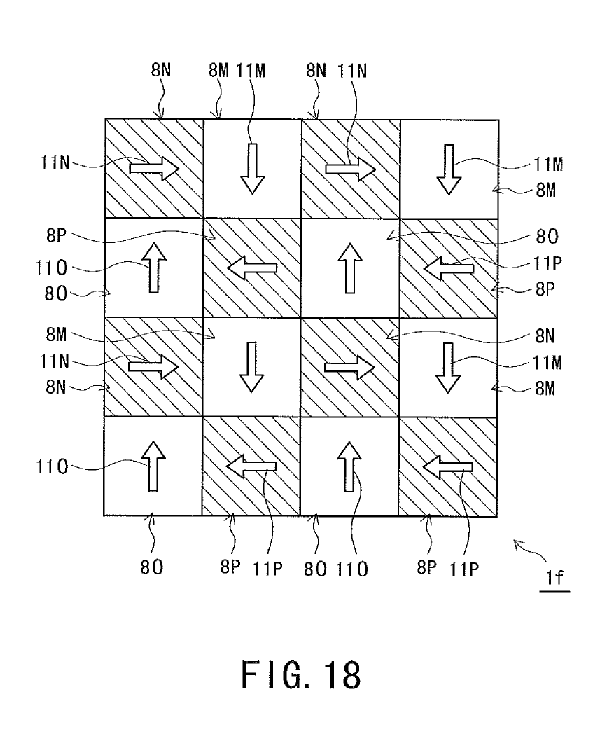

A detailed description of a method for photo-alignment treatment according to a sixth preferred embodiment of the present invention is provided with reference to FIGS. 16 to 18. In the method for photo-alignment treatment according to the sixth preferred embodiment of the present invention, two kinds of (a pair of) masks are used. FIG. 16 is a schematic view (plan view) illustrating a mask 3f of the paired masks that are used in the method for photo-alignment treatment according to the sixth preferred embodiment of the present invention. FIG. 17 is a schematic view (plan view) illustrating the other mask 3g that is used in the method for photo-alignment treatment according to the sixth preferred embodiment of the present invention. FIG. 18 is a schematic view (plan view) illustrating an alignment film material that is subjected to a photo-alignment treatment using the mask 3f shown in FIG. 16 and the mask 3g shown in FIG. 17. The mask 3f includes two kinds of polarizing plates 4M and polarizing plates 4N as shown in FIG. 16. Transmission axes 6M of the polarizing plates 4M are indicated with the arrows in solid lines in the polarizing plates 4M in FIG. 16, and absorption axes 7M of the polarizing plates 4M are indicated with the arrows in broken lines in the polarizing plates 4M in FIG. 16. Transmission axes 6N of the polarizing plates 4N are indicated with the arrows in solid lines in the polarizing plates 4N in FIG. 16, and absorption axes 7N of the polarizing plates 4N are indicated with the arrows in broken lines in the polarizing plates 4N in FIG. 16. The transmission axes 6M and the absorption axes 7M of the polarizing plates 4M intersect at right angles, and the transmission axes 6N and the absorption axes 7N of the polarizing plates 4N intersect at right angles. The transmission axes 6M of the polarizing plates 4M and the transmission axes 6N of the polarizing plates 4N are disposed vertical (perpendicular) to each other. The polarizing plates 4M and the polarizing plates 4N are disposed alternately in a lateral direction. In addition, the polarizing plates 4M and the polarizing plates 4N are disposed in a longitudinal direction while sandwiching light shielding frame members 5f. The mask 3g includes two kinds of polarizing plates 4O and polarizing plates 4P as shown in FIG. 17. Transmission axes 6O of the polarizing plates 4O are indicated with the arrows in solid lines in the polarizing plates 4O in FIG. 17, and absorption axes 7O of the polarizing plates 4O are indicated with the arrows in broken lines in the polarizing plates 4O in FIG. 17. Transmission axes 6P of the polarizing plates 4P are indicated with the arrows in solid lines in the polarizing plates 4P in FIG. 17, and absorption axes 7P of the polarizing plates 4P are indicated with the arrows in broken lines in the polarizing plates 4P in FIG. 17. The transmission axes 6O and the absorption axes 7O of the polarizing plates 4O intersect at right angles, and the transmission axes 6P and the absorption axes 7P of the polarizing plates 4P intersect at right angles. The transmission axes 6O of the polarizing plates 4O and the transmission axes 6P of the polarizing plates 4P are disposed vertical (perpendicular) to each other. The polarizing plates 4O and the polarizing plates 4P are disposed alternately in a lateral direction. In addition, the polarizing plates 4O and the polarizing plates 4P are disposed in a longitudinal direction while sandwiching light shielding frame members 5g.

First, the mask 3f shown in FIG. 16 is placed above an alignment film material, and the alignment film material is irradiated with linear polarized light 9M through the polarizing plates 4M and with linear polarized light 9N through the polarizing plates 4N of the mask 3f. Next, the mask 3f is replaced with the mask 3g shown in FIG. 17, and the mask 3g is placed above the alignment film material, and the alignment film material is irradiated with linear polarized light 9O through the polarizing plates 4O and with linear polarized light 9P through the polarizing plates 4P of the mask 3g. Thus, the alignment film material is subjected to the alignment treatment using the two kinds of (pair of) masks 3f and 3g, whereby an alignment film material if shown in FIG. 18 is obtained.

The linear polarized light 9M and the linear polarized light 9N shown in FIG. 16 are projected obliquely onto a surface of the alignment film material from different light sources (not shown). The linear polarized light 9M and the linear polarized light 9N are set to be vertical to each other when the mask 3f shown in FIG. 16 is seen in a plane view. In the present preferred embodiment of the present invention, planes of vibration of the linear polarized light 9M (planes including polarizing axes 10M) are disposed flush with transmission axes 6M of the polarizing plates 4M, and planes of vibration of the linear polarized light 9N (planes including polarizing axes 10N) are disposed flush with transmission axes 6N of the polarizing plates 4N. Domains 8M having alignment regulation powers (alignment regulation directions) 11M and domains 8N having alignment regulation powers (alignment regulation directions) 11N are formed on a surface of the alignment film material if shown in FIG. 18. The domains 8M are formed by the linear polarized light 9M having passed through the polarizing plates 4M, and the domains 8N are formed by the linear polarized light 9N having passed through the polarizing plates 4N of the mask 3f shown in FIG. 16.

The linear polarized light 9O and the linear polarized light 9P shown in FIG. 17 are projected obliquely onto the surface of the alignment film material from different light sources (not shown). The linear polarized light 9O and the linear polarized light 9P are set to be vertical to each other when the mask 3g shown in FIG. 17 is seen in a plane view. In the present preferred embodiment of the present invention, planes of vibration of the linear polarized light 9O (planes including polarizing axes 10O) are disposed flush with transmission axes 6O of the polarizing plates 4O, and planes of vibration of the linear polarized light 9P (planes including polarizing axes 10P) are disposed flush with transmission axes 6P of the polarizing plates 4P. Domains 8O having alignment regulation powers (alignment regulation directions) 11O and domains 8P having alignment regulation powers (alignment regulation directions) 11P are formed on the surface of the alignment film material if shown in FIG. 18. The domains 8O are formed by the linear polarized light 9O having passed through the polarizing plates 4O, and the domains 8P are formed by the linear polarized light 9P having passed through the polarizing plates 4P of the mask 3g shown in FIG. 17.

### REFERENCE EXAMPLE

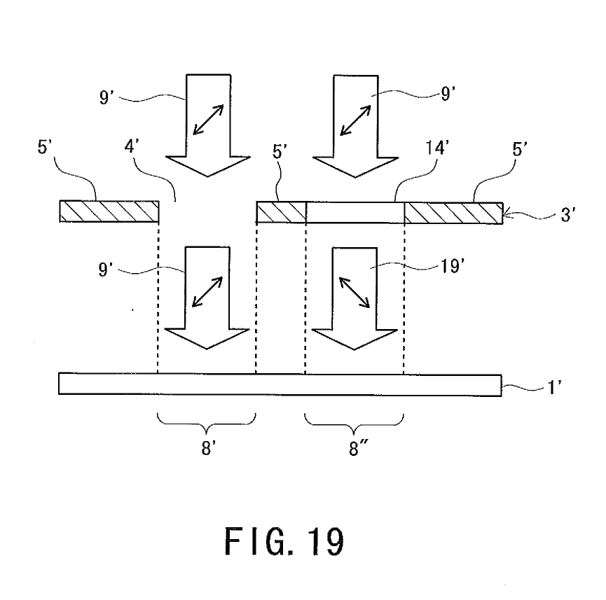

A description of a method for photo-alignment treatment according to a reference example is provided. FIG. 19 is a schematic view (cross-sectional view) illustrating the method for photo-alignment treatment according to another preferred embodiment of the present invention. An alignment film material 1′ and a mask 3′ disposed above the alignment film material 1′ are shown in FIG. 19. In this method, a surface of an alignment film material 1′ is irradiated in a vertical direction with linear polarized light 9′, whereby alignment regulation powers are developed thereon, and domains 8′ and 8″ for aligning liquid crystal molecules are formed. As shown in FIG. 19, the mask 3′ includes an opening portion (window) 4′at a position corresponding to the domain 8′, and a phase plate 14′ at a position corresponding to the domain 8″. The mask 3′ includes a light shielding frame member 5′ other than the opening portion 4′ and the phase plate 14′.

As shown in FIG. 19, when the linear polarized light 9′ is projected from a light source (not shown) disposed above the mask 3′, the linear polarized light 9′ passes directly through the opening portion 4′ and reaches the alignment film material 1′. In contrast, the linear polarized light 9′ projected onto the phase plate 14′ has its phase difference shifted by the phase plate 14′, and the light with its phase difference shifted reaches the alignment film material 1′. For example, in a case where a λ/2 phase plate is used as the phase plate 14′, when the linear polarized light 9′ passes through the phase plate 14′, linear polarized light 19′ having a polarizing axis (a plane of vibration) inclined 9O degrees reaches the surface of the alignment film material 1′. The linear polarized light 9 is shielded by the light shielding frame member 5′. Using the mask 3′ including the opening portion 4′ and the phase plate 14′ allows two kinds of linear polarized light that are different in polarizing axes (planes of vibration) to be obtained from one kind of linear polarized light. Thus, the domains 8′ and 8″ that have different alignment regulation powers (alignment regulation directions) can be formed at the same time on the alignment film material 1′.

That is, the method for photo-alignment treatment shown in FIG. 19 is a method for photo-alignment treatment for forming domains, which are sectioned with respect to alignment regulation directions, on a surface of an alignment film material that develops alignment regulation powers to align liquid crystal molecules in accordance with linear polarized light projected in a vertical direction, the method including irradiating the alignment film material surface with the linear polarized light in the vertical direction through a mask including a transmitting portion arranged to transmit the linear polarized light, and a phase plate arranged to shift a phase difference of the linear polarized light, the transmitting portion and the phase plate being disposed corresponding to the domains.

1. A method for photo-alignment treatment for forming domains, which are sectioned with respect to alignment regulation directions, on a surface of an alignment film material that develops alignment regulation powers to align liquid crystal molecules in accordance with irradiation directions of light, the method comprising
irradiating the alignment film material surface from different directions with different kinds of linear polarized light that have different planes of vibration through different kinds of polarizing plates, the polarizing plates having transmission axes being flush with the planes of vibration of the corresponding different kinds of linear polarized light, and being disposed corresponding to the domains, wherein a mask comprises the polarizing plates, and a light shielding supporting frame arranged to support the polarizing plates.

2. The method according to claim 1, wherein the irradiation of the alignment film material surface from the different directions with the different kinds of linear polarized light that have the different planes of vibration is performed at the same time.

3. The method according to claim 1, wherein the planes of vibration are perpendicular to each other.

4. The method according to claim 1, wherein the transmission axes are perpendicular to each other.

5. A mask for photo-alignment treatment that is used for irradiating a surface of an alignment film material, which develops alignment regulation powers to align liquid crystal molecules in accordance with irradiation directions of light, with different kinds of linear polarized light that have different planes of vibration through different kinds of polarizing plates provided to the mask, and forming domains, which are sectioned with respect to alignment regulation directions, on the alignment film material surface, the mask comprising:
the polarizing plates that have transmission axes being flush with the planes of vibration of the corresponding different kinds of linear polarized light, and are disposed corresponding to the domains; and
a light shielding supporting frame arranged to support the polarizing plates.

6. The mask according to claim 5, wherein the transmission axes are perpendicular to each other.

7. A method for producing an alignment film, the method comprising a process of forming domains, which are sectioned with respect to alignment regulation directions, on a surface of an alignment film material that develops alignment regulation powers to align liquid crystal molecules in accordance with irradiation directions of light, the process comprising
irradiating the alignment film material surface from different directions with different kinds of linear polarized light that have different planes of vibration through different kinds of polarizing plates, the polarizing plates having transmission axes being flush with the planes of vibration of the corresponding different kinds of linear polarized light, and being disposed corresponding to the domains, wherein a mask comprises the polarizing plates, and a light shielding supporting frame arranged to support the polarizing plates.

8. The method according to claim 7, wherein the irradiation of the alignment film material surface from the different directions with the different kinds of linear polarized light that have the different planes of vibration is performed at the same time.

9. The method according to claim 7, wherein the planes of vibration are perpendicular to each other.

10. The method according to claim 7, wherein the transmission axes are perpendicular to each other.
